(19) United States
(12) Patent Application Publication
(10) Pub. No.: US 2023/0395611 A1
(43) Pub. Date: Dec. 7, 2023

(54) SEMICONDUCTOR SUBSTRATE AND ELECTRONIC DEVICE

(71) Applicant: Japan Display Inc., Tokyo (JP)

(72) Inventor: Gen KOIDE, Tokyo (JP)

(73) Assignee: Japan Display Inc., Tokyo (JP)

(21) Appl. No.: 18/365,460

(22) Filed: Aug. 4, 2023

Related U.S. Application Data
(63) Continuation of application No. PCT/JP2021/043428, filed on Nov. 26, 2021.

(30) Foreign Application Priority Data
Feb. 4, 2021 (JP) 2021-016569

(51) Int. Cl. H01L 27/12

(52) U.S. Cl. CPC H01L 27/124; G02F 1/136286

(57) ABSTRACT

According to one embodiment, a semiconductor substrate includes an insulating substrate, a plurality of gate lines, a plurality of source lines, a first electronic circuit formed above the insulating substrate, a first lead line provided with a first signal, a second lead line electrically connected to the first electronic circuit, and a first inductor. The first inductor is provided above the insulating substrate and is electrically connected between the first lead line and the second lead line.

### CROSS-REFERENCE TO RELATED APPLICATIONS

This application is a Continuation Application of PCT Application No. PCT/JP2021/043428, filed Nov. 26, 2021 and based upon and claiming the benefit of priority from Japanese Patent Application No. 2021-016569, filed Feb. 4, 2021, the entire contents of all of which are incorporated herein by reference.

### FIELD

Embodiments described herein relate generally to a semiconductor substrate and an electronic device.

### BACKGROUND

Electro-magnetic compatibility (EMC) standards for electronic devices such as display devices are becoming stricter. For example, it is required to reduce the level of radiation noise (electro-magnetic interference (EMI)) from display devices. Therefore, there is a need to solve the problem of large levels of radiation noise in an AM frequency band from various drive signals, power supplies, etc., in display panels such as liquid crystal display panels.

### BRIEF DESCRIPTION OF THE DRAWINGS

FIG. 1 is a perspective view schematically showing a configuration of a liquid crystal display device with a sensor according to a first embodiment.

FIG. 2 is a diagram schematically showing a basic configuration and an equivalent circuit of the liquid crystal display device shown in FIG. 1.

FIG. 3 is an equivalent circuit diagram showing a pixel shown in FIG. 2.

FIG. 4 is a cross-sectional view showing a part of the structure of the liquid crystal display device.

FIG. 5 is a circuit diagram showing a part of the liquid crystal display device.

FIG. 6 is a plan view schematically showing a configuration of a sensor in the first embodiment.

FIG. 7 illustrates a principle of an example of a sensing method.

FIG. 8 is a circuit diagram showing a part of a liquid crystal display device with a sensor according to a second embodiment.

FIG. 9 is a plan view showing one of a plurality of inductors in FIG. 8 and a magnetic material.

FIG. 10 is a cross-sectional view showing a part of a first substrate according to the second embodiment along line X-X of FIG. 9.

### DETAILED DESCRIPTION

In general, according to one embodiment, there is provided a semiconductor substrate comprising: an insulating substrate; a plurality of gate lines and a plurality of source lines formed above the insulating substrate; a first electronic circuit formed above the insulating substrate and connected to the plurality of gate lines; a first lead line formed above the insulating substrate and provided with a first signal; a second lead line formed above the insulating substrate and electrically connected to the first electronic circuit; and a first inductor provided above the insulating substrate and electrically connected between the first lead line and the second lead line.

According to another embodiment, there is provided an electronic device comprising: a semiconductor substrate including an insulating substrate, a plurality of gate lines and a plurality of source lines formed above the insulating substrate, a first electronic circuit formed above the insulating substrate and connected to the plurality of gate lines, a first lead line formed above the insulating substrate and provided with a first signal, and a second lead line formed above the insulating substrate and electrically connected to the first electronic circuit; a wiring substrate including a third lead line electrically connected to the first lead line and a fourth lead line electrically connected to the second lead line, and coupled to the semiconductor substrate; and a first inductor provided on the wiring substrate and electrically connected between the third lead line and the fourth lead line.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

### First Embodiment

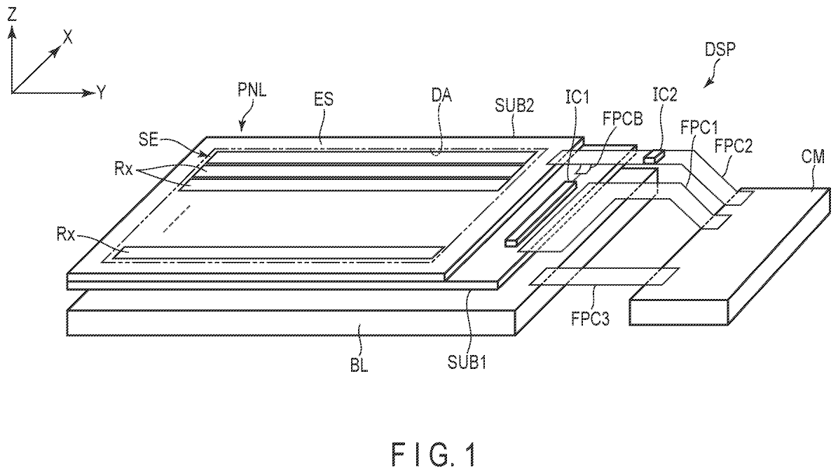

First, a display device with a sensor according to a first embodiment will be described in detail. In the present embodiment, a case in which the display device, which is an electronic device, is a liquid crystal display device will be described. FIG. 1 is a perspective view schematically showing the liquid crystal display device with a sensor according to the present embodiment.

As shown in FIG. 1, a liquid crystal display device DSP comprises an active matrix liquid crystal display panel PNL, a drive IC chip IC1 that drives the liquid crystal display panel PNL, a capacitive sensor SE, a drive IC chip IC2 that drives the sensor SE, a backlight unit BL that illuminates the liquid crystal display panel PNL, a control module CM, flexible wiring substrates FPC1, FPC2, FPC3, etc.

The liquid crystal display panel PNL comprises a flat first substrate SUB1, a flat second substrate SUB2 arranged facing the first substrate SUB1, and a liquid crystal layer (liquid crystal layer LC described below) sandwiched between the first substrate SUB1 and the second substrate SUB2. Note that, in the present embodiment, the first substrate SUB1 and the second substrate SUB2 can be rephrased as an array substrate and a counter-substrate, respectively. The liquid crystal display panel PNL comprises a display area (active area) DA for displaying images. This liquid crystal display panel PNL is a transmissive liquid crystal display panel with a transmissive display function that displays images by selectively transmitting backlight from the backlight unit BL. Note that, in addition to the transmissive display function, the liquid crystal display panel PNL may be a semi-transmissive liquid crystal display panel with a reflective display function that displays images by selectively reflecting outside light.

The backlight unit BL is arranged on a back surface side of the first substrate SUB1. Various forms of such a backlight unit BL are applicable, and those utilizing a light-emitting diode (LED) as a light source, etc., are also applicable, for which description of detailed structures will be omitted. Note that, in a case where the liquid crystal display panel PNL is a reflective type equipped with only a reflective display function, the backlight unit BL is omitted.

The sensor SE comprises a plurality of detection electrodes Rx. These detection electrodes Rx are provided, for example, above an outer surface ES on a screen side of the liquid crystal display panel PNL that displays images. Therefore, the detection electrodes Rx may be in contact with the outer surface ES or may be located away from the outer surface ES. In the latter case, a material such as an insulating layer is interposed between the outer surface ES and the detection electrode Rx. In the present embodiment, the detection electrode Rx is in contact with the outer surface ES. Here, the outer surface ES is a surface on the opposite side of a surface of the second substrate SUB2 facing the first substrate SUB1 and includes a display surface that displays images. In addition, in the illustrated example, each detection electrode Rx extends generally in a columnar direction Y and is aligned in a row direction X, which intersects the columnar direction Y. A thickness direction Z of the liquid crystal display panel PNL is orthogonal to the row direction X and the columnar direction Y, respectively. In the present embodiment, the row direction X is a first direction, the columnar direction Y is a second direction, and the thickness direction Z is a third direction. Note that each detection electrode Rx may be extended in the row direction X and aligned in the columnar direction Y, or may be formed as an island and arranged in a matrix in the row direction X and the columnar direction Y. Here, the row direction X and the columnar direction Y are orthogonal to each other.

The drive IC chip IC1 as a first drive unit is mounted on the first substrate SUB1 of the liquid crystal display panel PNL. The flexible wiring substrate FPC1 is configured by, for example, a flexible printed circuit (FPC) as a wiring substrate. The flexible wiring substrate FPC1 connects the liquid crystal display panel PNL and the control module CM. The flexible wiring substrate FPC2 connects the detection electrode Rx of the sensor SE and the control module CM. The drive IC chip IC2 as a second drive unit is mounted on the flexible wiring substrate FPC2. The flexible wiring substrate FPC3 connects the backlight unit BL and the control module CM. Here, the control module CM can be rephrased as an application processor.

The drive IC chip IC1 and the drive IC chip IC2 are connected via the flexible wiring substrate FPC2, etc. For example, in a case where the flexible wiring substrate FPC2 has a branch portion FPCB connected on the first substrate SUB1, the drive IC chip IC1 and the drive IC chip IC2 may be connected via the branch portion FPCB and a wiring line on the first substrate SUB1. The drive IC chip IC1 and drive IC chip IC2 may also be connected via the flexible wiring substrates FPC1 and FPC2. The drive IC chip IC2 can provide the drive IC chip IC1 with a timing signal that informs when to drive the sensor SE. Alternatively, the drive IC chip IC1 can provide the drive IC chip IC2 with a timing signal that informs when to drive a common electrode CE described later. Alternatively, the control module CM can provide timing signals to the drive IC chips IC1 and IC2. The above timing signals can attempt to synchronize the drive of the drive IC chip IC1 with the drive of the drive IC chip IC2.

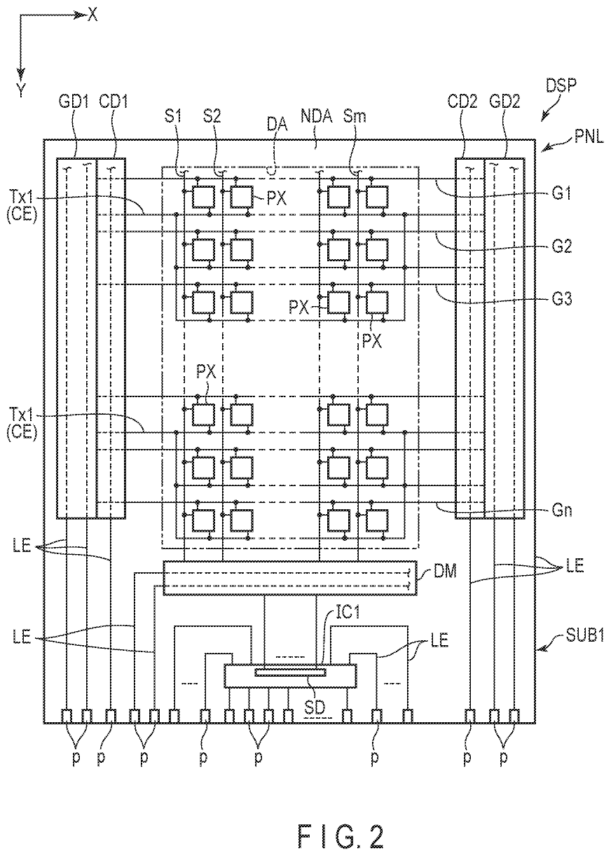

FIG. 2 is a diagram schematically showing a basic configuration and an equivalent circuit of the liquid crystal display device DSP shown in FIG. 1.

As shown in FIG. 2, the liquid crystal display device DSP comprises, in addition to the liquid crystal display panel PNL, etc., a drive IC chip IC1, etc. located in a non-display area NDA outside the display area DA. In the present embodiment, the drive IC chip IC1 comprises a source line driving circuit SD. The liquid crystal display panel PNL comprises gate line driving circuits GD1 and GD2, common electrode driving circuits CD1 and CD2, and a demultiplexer DM located in the non-display area NDA.

Note that, instead of the drive IC chip IC1, the liquid crystal display panel PNL may comprise the source line driving circuit SD located in the non-display area NDA. The shape of the non-display area NDA is a frame shape (rectangular frame shape) surrounding the display area DA.

The liquid crystal display panel PNL comprises a plurality of pixels PX in the display area DA. The plurality of pixels PX are provided in a matrix in the row direction X and the columnar direction Y, and are arranged in m×n units (however, m and n are positive integers). The liquid crystal display panel PNL is also provided with n gate lines G (G1 to Gn), m source lines S (S1 to Sm), and a common electrode CE in the display area DA.

The gate lines G extend substantially linearly in the row direction X, are drawn outside the display area DA, and are electrically connected to the gate line driving circuits GD1 and GD2. The gate lines G are spaced apart in the columnar direction Y.

The source lines S extend substantially linearly in the columnar direction Y, are drawn outside the display area DA, and are electrically connected to the demultiplexer DM. The demultiplexer DM is electrically connected to the drive IC chip IC1 (source line driving circuit SD). The source lines S are spaced apart in the row direction X and intersect the gate lines G. Note that the gate lines G and the source lines S do not necessarily have to extend linearly, and some of them may be bent.

The common electrodes CE are provided at least within the display area DA and are electrically connected to the common electrode driving circuits CD1 and CD2. The common electrodes CE have a plurality of electrodes Tx. Each electrode Tx is shared by a plurality of pixels PX. Details of the common electrodes CE are described below.

In the drawing, the gate line driving circuit GD1 and the common electrode driving circuit CD1 are located on the left side of the display area DA, and the gate line driving circuit GD2 and the common electrode driving circuit CD2 are located on the right side of the display area DA. Note that the liquid crystal display panel PNL should have at least a single gate line driving circuit GD and a single common electrode driving circuit CD. For example, the liquid crystal display panel PNL may be formed without the gate line driving circuit GD2 and the common electrode driving circuit CD2.

Although the common electrode driving circuit CD is located between the display area DA and the gate line driving circuit GD, the positional relationship between the common electrode driving circuit CD and the gate line driving circuit GD is not limited to the relationship in FIG. 2. For example, the gate line driving circuit GD may be located between the display area DA and the common electrode driving circuit CD.

In the first substrate SUB1, a plurality of pads p of outer lead bonding (OLB) are lined up in the area not facing the second substrate SUB2. A plurality of electronic circuits such as the drive IC chip IC1 (source line driving circuit SD), the demultiplexer DM, the gate line driving circuits GD1 and GD2, and the common electrode driving circuits CD1 and CD2 are electrically connected to the pads p via lead lines LE.

Note that the plurality of electronic circuits use active elements such as thin-film transistors (TFT). From the above, the first substrate SUB1 is a semiconductor substrate. The configuration of the electronic circuits is generally known, and the configuration of electronic circuits disclosed in JP 2014-199605 A, JP 2015-230400 A, etc., can be applied to the embodiment.

The flexible wiring substrate FPC1 is coupled to the first substrate SUB1 (liquid crystal display panel PNL). For example, a thermo-compression bonding method utilizing an anisotropic conductive film (ACF) is used to connect the flexible wiring substrate FPC1 and the first substrate SUB1. This method ensures electrical connection between the plurality of pads p of the first substrate SUB1 and a plurality of pads of the flexible wiring substrate FPC1.

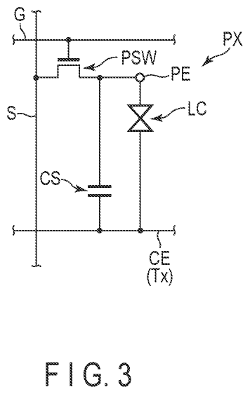

FIG. 3 is an equivalent circuit diagram showing the pixel PX shown in FIG. 2.

As shown in FIG. 3, each pixel PX comprises a pixel switching element PSW, a pixel electrode PE, a common electrode CE, a liquid crystal layer LC, etc. The pixel switching element PSW is formed by a TFT, for example. The pixel switching element PSW is electrically connected to the gate line G and the source line S.

The pixel switching element PSW may be either a top-gate TFT or a bottom-gate TFT. A semiconductor layer of the pixel switching element PSW is formed by polycrystalline silicon, for example, but may also be formed by amorphous silicon or oxide semiconductor. The pixel electrode PE is electrically connected to the pixel switching element PSW. The pixel electrode PE faces the common electrode CE. The common electrode CE, an insulating layer, and the pixel electrode PE form a storage capacitor CS.

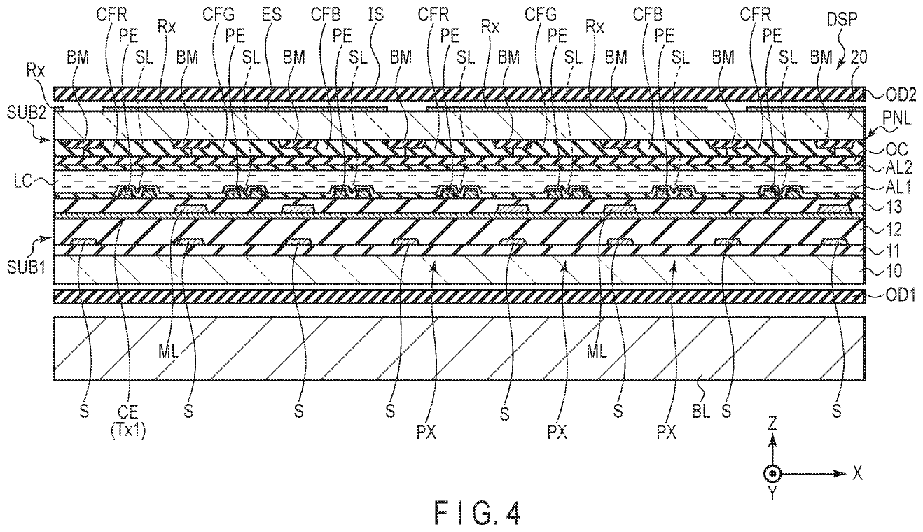

FIG. 4 is a cross-sectional diagram showing a part of the structure of the liquid crystal display device DSP.

As shown in FIG. 4, the liquid crystal display device DSP comprises a first optical element OD1, a second optical element OD2, etc., in addition to the liquid crystal display panel PNL and the backlight unit BL described above. Note that the liquid crystal display panel PNL shown in the drawing has a configuration corresponding to a fringe field switching (FFS) mode, which is an example of in-plane switching (IPS) as a display mode, but it may have a configuration corresponding to other display modes.

For example, the liquid crystal display panel PNL may have a configuration corresponding to an in-plane switching (IPS) mode, which mainly utilizes a lateral electric field substantially parallel to a substrate main surface, such as an FFS mode. In a display mode that utilizes a lateral electric field, for example, a configuration in which both the pixel electrode PE and the common electrode CE are provided on the first substrate SUB1 can be applied. Alternatively, the liquid crystal display panel PNL may have a configuration corresponding to a mode that mainly utilizes a longitudinal electric field that is substantially perpendicular to the substrate main surface, such as a twisted nematic (TN) mode, an optically compensated bend (OCB) mode, a vertical aligned (VA) mode, etc. In a display mode that utilizes a longitudinal electric field, for example, a configuration in which the first substrate SUB1 is provided with the pixel electrode PE and the second substrate SUB2 is provided with the common electrode CE can be applied. Note that the substrate main surface here is a surface parallel to an X-Y plane defined by the row direction X and the columnar direction Y which are orthogonal to each other.

The liquid crystal display panel PNL comprises the first substrate SUB1, the second substrate SUB2, and the liquid crystal layer LC. The first substrate SUB1 and the second substrate SUB2 are pasted together maintaining a predetermined gap. The liquid crystal layer LC is sealed in the gap between the first substrate SUB1 and the second substrate SUB2.

The first substrate SUB1 is formed using an optically transparent first insulating substrate 10, such as a glass substrate or a resin substrate. The first substrate SUB1 comprises the source line S, the common electrode CE, the pixel electrode PE, a first insulating layer 11, a second insulating layer 12, a third insulating layer 13, and a first alignment film AL1 on the first insulating substrate 10 side facing the second substrate SUB2. For example, the pixel electrode PE and the common electrode CE are formed above the first insulating substrate 10 and are located in the display area DA.

The first insulating layer 11 is arranged on the first insulating substrate 10. Note that, although not described in detail, in the present embodiment, for example, a pixel switching element with a top-gate structure is applied. In such an embodiment, the first insulating layer 11 includes a plurality of insulating layers stacked in the thickness direction Z. For example, the first insulating layer 11 includes various insulating layers, such as an undercoat layer interposed between the first insulating substrate 10 and a semiconductor layer of a pixel switching element, a gate insulating layer interposed between the semiconductor layer and a gate electrode, and an interlayer insulating layer interposed between the gate electrode and source and drain electrodes.

The gate line (G) is arranged between the gate insulating layer and the interlayer insulating layer in the same manner as the gate electrode. The source line S is formed on the first insulating layer 11. The source electrode and the drain electrode of the pixel switching element, etc. are also formed on the first insulating layer 11. In the illustrated example, the source line S extends in the columnar direction Y.

The second insulating layer 12 is arranged on the source line S and the first insulating layer 11. The common electrode CE is formed on the second insulating layer 12. The common electrode CE is formed by a transparent conductive material such as indium tin oxide (ITO), indium zinc oxide (IZO), zinc oxide (ZnO), or the like. Note that, in the example shown in the drawing, a metal layer ML is formed on the electrode Tx of the common electrode CE to make the common electrode CE low-resistance. However, the metal layer ML may be omitted.

The third insulating layer 13 is arranged on the common electrode CE and the second insulating layer 12. The pixel electrode PE is formed on the third insulating layer 13. Each pixel electrode PE is located between a pair of adjacent source lines S, respectively, and faces the common electrode CE (electrode Tx). Each pixel electrode PE has a slit SL at a location facing the common electrode CE. Such pixel electrodes PE are made of a transparent conductive material such as ITO or IZO. The first alignment film AL1 covers the pixel electrode PE and the third insulating layer 13.

On the other hand, the second substrate SUB2 is formed using an optically transparent second insulating substrate 20, such as a glass substrate or a resin substrate. The second substrate SUB2 comprises a black matrix BM, color filters CFR, CFG, and CFB, an overcoat layer OC, a second alignment film AL2, etc., on the second insulating substrate 20 side facing the first substrate SUB1.

The black matrix BM is formed on an inner surface of the second insulating substrate 20 and defines each pixel. The color filters CFR, CFG, and CFB are formed on the inner surface of the second insulating substrate 20, respectively, and a part of them overlaps the black matrix BM. The color filter CFR is a red filter arranged in a red pixel and is formed by a red resin material. The color filter CFG is a green filter arranged in a green pixel and formed by a green resin material. The color filter CFB is a blue filter arranged in a blue pixel, and is formed by a blue resin material.

The illustrated example corresponds to a case in which a unit pixel, which is the smallest unit configuring a color image, is configured by three color pixels such as a red pixel, a green pixel, and a blue pixel. However, the unit pixel is not limited to the combination of the above three color pixels. For example, the unit pixel may be configured by four color pixels including a white pixel in addition to the red pixel, the green pixel, and the blue pixel. In this case, a white filter or a transparent filter may be arranged in the white pixel, or the filter of the white pixel itself may be omitted.

The overcoat layer OC covers the color filters CFR, CFG, and CFB. The overcoat layer OC is formed by a transparent resin material. The second alignment film AL2 covers the overcoat layer OC.

The detection electrode Rx is formed above the surface of the second insulating substrate 20 (outer surface ES). The detailed structure of this detection electrode Rx is described below. In this embodiment, the detection electrode Rx is formed by a transparent conductive material such as ITO or IZO. Note that the detection electrode Rx may be formed by a metal, for example, as a conductive material. By lowering the electrical resistance of the detection electrode Rx, the time required for detection can be reduced.

Therefore, forming the detection electrode Rx with metal is advantageous for a larger size and higher resolution of the liquid crystal display panel PNL. Alternatively, the detection electrode Rx may be formed by a combination (aggregate) of metal (e.g., metal wire) and a transparent conductive material (e.g., transparent conductive layer).

Each detection electrode Rx faces a plurality of electrodes (sensor drive electrodes) Tx through the third insulating layer 13, the first alignment film AL1, the liquid crystal layer LC, the second alignment film AL2, the overcoat layer OC, the color filters CFR, CFG, CFB and the second insulating substrate 20.

The first optical element OD1 is arranged between the first insulating substrate 10 and the backlight unit BL. The second optical element OD2 is arranged above the detection electrode Rx. The first optical element OD1 and the second optical element OD2 each include at least a polarizer and may include a retardation film if necessary. An absorption axis of the polarizer included in the first optical element OD1 and an absorption axis of the polarizer included in the second optical element OD2 are orthogonal to each other. In addition, in this example, an input surface IS of the liquid crystal display device DSP is the surface of the second optical element OD2. The liquid crystal display device DSP is capable of detecting position information of a point where an input means such as a finger contacts or approaches the input surface IS.

Next, an operation during display drive for displaying an image in the FFS mode liquid crystal display device DSP, which is an example of the IPS, will be described.

First, an off state in which no voltage is applied to the liquid crystal layer LC is explained. The off state corresponds to a state in which no potential difference is formed between the pixel electrode PE and the common electrode CE. In such an off state, liquid crystal molecules included in the liquid crystal layer LC are initially aligned in one direction in the X-Y plane by the alignment restriction force of the first alignment film AL1 and the second alignment film AL2.

A part of the backlight from the backlight unit BL passes through the polarizer of the first optical element OD1 and is incident on the liquid crystal display panel PNL. The light incident on the liquid crystal display panel PNL is linearly polarized light orthogonal to the absorption axis of the polarizer. The polarized state of such linearly polarized light hardly changes when passing through the liquid crystal display panel PNL in the off state. Therefore, most of the linearly polarized light transmitted through the liquid crystal display panel PNL is absorbed by the polarizer of the second optical element OD2 (black display). This mode in which the liquid crystal display panel PNL is displayed in black in the off state is referred to as a normally black mode.

Next, an on state in which voltage is applied to the liquid crystal layer LC is described. The on state corresponds to a state in which a potential difference is formed between the pixel electrode PE and the common electrode CE. In other words, a common drive signal (common voltage) is supplied to the common electrode CE from the common electrode driving circuit CD. On the other hand, the pixel electrode PE is supplied with a video signal that forms a potential difference with respect to the common voltage, which is a constant voltage. As a result, a lateral electric field (fringe electric field) is formed between the pixel electrode PE and the common electrode CE in the on state.

In such an on state, the liquid crystal molecules are aligned in an orientation different from the initially aligned direction in the X-Y plane. In the on state, the linearly polarized light orthogonal to the absorption axis of the polarizer of the first optical element OD1 is incident on the liquid crystal display panel PNL, and its polarized state changes according to the aligned state of the liquid crystal molecules when passing through the liquid crystal layer LC. Therefore, in the on state, at least some of the light that passes through the liquid crystal layer LC transmits through the polarizer of the second optical element OD2 (white display).

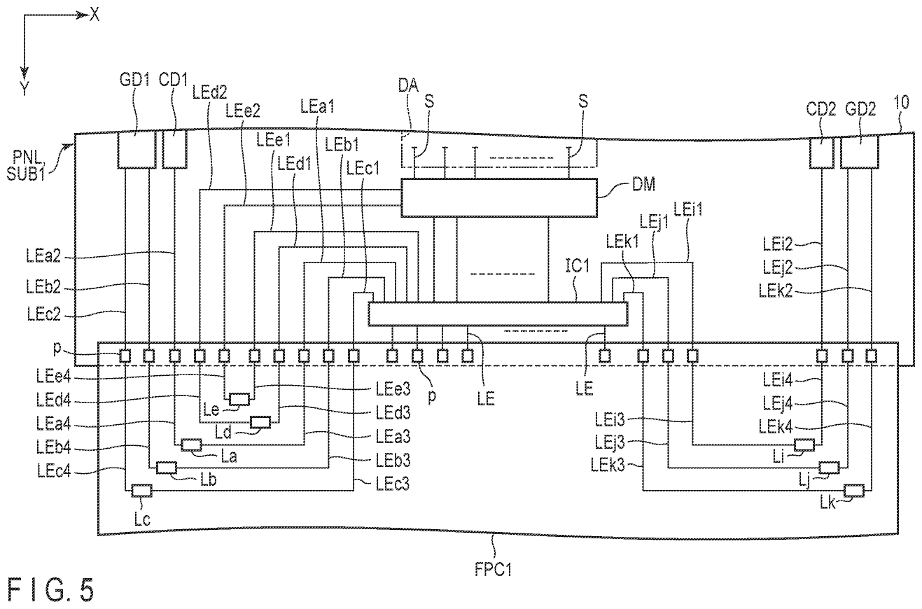

FIG. 5 is a circuit diagram showing a part of the liquid crystal display device DSP.

As shown in FIG. 5, signals are input to the drive IC chip IC1 from the flexible wiring substrate FPC1 via the lead lines LE, etc. The drive IC chip IC1 outputs video signals to the demultiplexer DM, which selectively outputs the input video signals to a plurality of source lines S.

The common electrode driving circuits CD1 and CD2, the gate line driving circuits GD1 and GD2, and the demultiplexer DM are formed above the first insulating substrate 10.

The gate line driving circuits GD1 and GD2 are electrically connected to a plurality of pixel switching elements PSW via the gate lines G. The gate line driving circuits GD1 and GD2 are circuits for controlling the timing of switching the pixel switching elements PSW on (conductive state) and off (non-conductive state).

The common electrode driving circuits CD1 and CD2 are electrically connected to the common electrode CE (plurality of electrodes Tx). The common electrode driving circuits CD1 and CD2 are circuits for driving the common electrode CE (plurality of electrodes Tx).

The demultiplexer DM is electrically connected to a plurality of pixel electrodes PE via a plurality of source lines S and a plurality of pixel switching elements PSW. The demultiplexer DM is a circuit for driving the plurality of pixel electrodes PE and provides video signals to the plurality of pixel electrodes PE.

A plurality of lead lines LE are formed above the first insulating substrate 10. Lead lines LEa1, LEb1, LEc1, LEd1, LEe1, LEi1, LEj1, and LEk1 are electrically connected to the drive IC chip IC1 and a corresponding pad p, respectively.

A lead line LEa2 is electrically connected to the common electrode driving circuit CD1 and a corresponding pad p. For example, the lead line LEa2 extends inside the common electrode driving circuit CD1.

Lead lines LEb2 and LEc2 are electrically connected to the gate line driving circuit GD1 and a corresponding pad p, respectively. For example, the lead lines LEb2 and LEc2 extend inside the gate line driving circuit GD1, respectively.

Lead lines LEd2 and LEe2 are electrically connected to the demultiplexer DM and a corresponding pad p, respectively. For example, the lead lines LEd2 and LEe2 extend inside the demultiplexer DM.

A lead line LEi2 is electrically connected to the common electrode driving circuit CD2 and a corresponding pad p. For example, the lead line LEi2 extends inside the common electrode driving circuit CD2.

Lead lines LEj2 and LEk2 are electrically connected to the gate line driving circuit GD2 and a corresponding pad p, respectively. For example, the lead lines LEj2 and LEk2 extend inside the gate line driving circuit GD2.

The plurality of lead lines LE of the first substrate SUB1 may be simultaneously formed of the same material as one or more of the gate lines G, the source lines S, and the metal layer ML.

The flexible wiring substrate FPC1 has a plurality of lead lines LE.

A lead line LEa3 is electrically connected to the lead line LEa1 via the corresponding pad p. A lead line LEa4 is electrically connected to the lead line LEa2 via the corresponding pad p.

A lead line LEb3 is electrically connected to the lead line LEb1 via the corresponding pad p. A lead line LEb4 is electrically connected to the lead line LEb2 via the corresponding pad p.

A lead line LEc3 is electrically connected to the lead line LEc1 via the corresponding pad p. A lead line LEc4 is electrically connected to the lead line LEc2 via the corresponding pad p.

A lead line LEd3 is electrically connected to the lead line LEd1 via the corresponding pad p. A lead line LEd4 is electrically connected to the lead line LEd2 via the corresponding pad p.

A lead line LEe3 is electrically connected to the lead line LEe1 via the corresponding pad p. A lead line LEe4 is electrically connected to the lead line LEe2 via the corresponding pad p.

A lead line LEi3 is electrically connected to the lead line LEi1 via the corresponding pad p. A lead line LEi4 is electrically connected to the lead line LEi2 via the corresponding pad p.

A lead line LEj3 is electrically connected to the lead line LEj1 via the corresponding pad p. A lead line LEj4 is electrically connected to the lead line LEj2 via the corresponding pad p.

A lead line LEk3 is electrically connected to the lead line LEk1 via the corresponding pad p. A lead line LEk4 is electrically connected to the lead line LEk2 via the corresponding pad p.

The liquid crystal display device DSP further comprises a plurality of inductors L. The plurality of inductors L are provided on the flexible wiring substrate FPC1.

An inductor La is electrically connected between the lead lines LEa3 and LEa4. The lead line LEa3, the inductor La, and the lead line LEa4 are connected in series.

An inductor Lb is electrically connected between the lead lines LEb3 and LEb4.

An inductor Lc is electrically connected between the lead lines LEc3 and LEc4.

An inductor Ld is electrically connected between the lead lines LEd3 and LEd4.

An inductor Le is electrically connected between the lead lines LEe3 and LEe4.

An inductor Li is electrically connected between the lead lines LEi3 and LEi4.

An inductor Lj is electrically connected between the lead lines LEj3 and LEj4.

An inductor Lk is electrically connected between the lead lines LEk3 and LEk4.

In the present embodiment, each inductor L is a ferrite bead and is mounted on the flexible wiring substrate FPC1. However, the inductor L may be a coil. For example, the coil may be formed inside the flexible wiring substrate FPC1. Alternatively, the coil may be an external type coil and mounted on the flexible wiring substrate FPC1.

The drive IC chip IC1 controls the drive of the common electrode driving circuits CD1 and CD2, the gate line driving circuits GD1 and GD2, and the demultiplexer DM, respectively.

A drive signal TSVcom is given from the drive IC chip IC1 to the lead line LEa1, and the drive signal TSVcom is given to the common electrode driving circuit CD1 via the lead line LEa1, the lead line LEa3, the inductor La, the lead line LEa4, and the lead line LEa2.

A gate enable signal ENB is given to lead line LEb1 from the drive IC chip IC1, and the gate enable signal ENB is given to the gate line driving circuit GD1 via lead line LEb1, the lead line LEb3, the inductor Lb, the lead line LEb4, and the lead line LEb2.

A clock signal CKV is given to the lead line LEc1 from the drive IC chip IC1, and the clock signal CKV is given to the gate line driving circuit GD1 via the lead line LEc1, the lead line LEc3, the inductor Lc, the lead line LEc4, and the lead line LEc2.

Note that multiple types of gate enable signals ENB may be given to the gate line driving circuit GD1 simultaneously. In this case, separate lead lines LE and inductor Lb should be prepared and electrically connected to the drive IC chip IC1 and the gate line driving circuit GD1.

A control signal ASW1 is given to the lead line LEd1 from the drive IC chip IC1, and the control signal ASW1 is given to the demultiplexer DM via the lead line LEd1, the lead line LEd3, the inductor Ld, the lead line LEd4, and the lead line LEd2.

A control signal ASW2 is given to the lead line LEe1 from the drive IC chip IC1, and the control signal ASW2 is given to the demultiplexer DM via the lead line LEe1, the lead line LEe3, the inductor Le, the lead line LEe4, and the lead line LEe2.

The control signals ASW1 and ASW2 control the driving of analog switches inside the demultiplexer DM.

The drive signal TSVcom is given to the lead line LEi1 from the drive IC chip IC1, and the drive signal TSVcom is given to the common electrode driving circuit CD2 via the lead line LEi1, the lead line LEi3, the inductor Li, the lead line LEi4, and the lead line LEi2.

The gate enable signal ENB is given to the lead line LEj1 from the drive IC chip IC1, and the gate enable signal ENB is given to the gate line driving circuit GD2 via the lead line LEj1, the lead line LEj3, the inductor Lj, the lead line LEj4, and the lead line LEj2.

The clock signal CKV is given to the lead line LEk1 from the drive IC chip IC1, and the clock signal CKV is given to the gate line driving circuit GD2 via the lead line LEk1, the lead line LEk3, the inductor Lk, the lead line LEk4, and the lead line LEk2.

Multiple types of gate enable signals ENB may be given to the gate line driving circuit GD2 simultaneously.

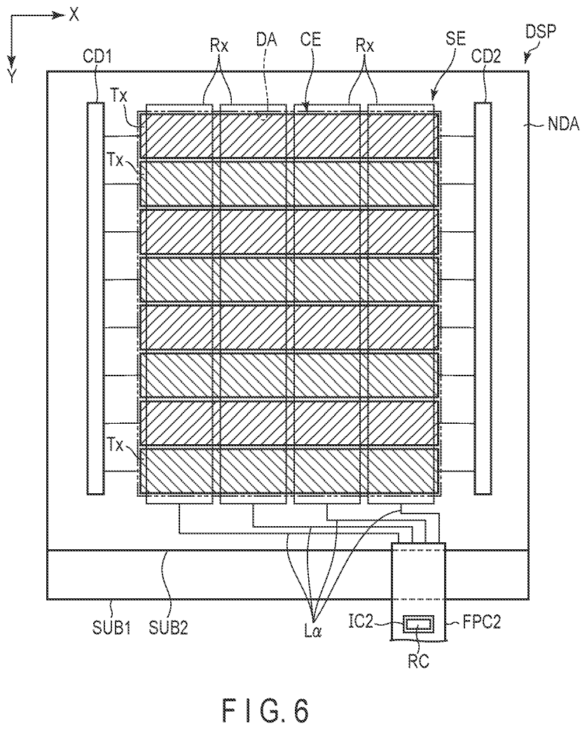

Next, the capacitive sensor SE included in the liquid crystal display device DSP of the present embodiment will be explained. FIG. 6 is a plan view schematically showing a configuration of the sensor SE in the present embodiment. In FIG. 6, the above drive IC chip IC1 is omitted.

As shown in FIG. 6, the sensor SE of the present embodiment comprises the common electrode CE on the first substrate SUB1 side and the detection electrode Rx and a draw-out line La, etc., on the second substrate SUB2 side. In other words, the common electrode CE functions as a display electrode and as a sensor drive electrode.

The common electrode CE and the detection electrode Rx are arranged at least in the display area DA. The common electrode CE has a plurality of electrodes (sensor drive electrodes) Tx. In the illustrated example, the plurality of electrodes Tx are formed in a band shape in the display area DA, each extending substantially linearly in the row direction X and spaced apart in the columnar direction Y.

In the present embodiment, for convenience, the common electrode CE is described as having eight electrodes Tx. However, the number of electrodes Tx is not particularly limited and can be changed in various ways, and the common electrode CE may have a plurality of electrodes Tx other than eight.

In the present embodiment, the common electrode driving circuits CD1 and CD2 provide common drive signals to the electrodes Tx during the display drive for displaying images. The common electrode driving circuits CD1 and CD2 write a write signal to the electrode Tx during sensing drive for performing sensing.

The detection electrodes Rx are spaced apart in the row direction X and extend substantially linearly in the columnar direction Y in the display area DA, respectively. In other words, here, the detection electrodes Rx extend in a direction that intersects the electrode Tx. Note that the number, size, and shape of the detection electrodes Rx are not particularly limited and can be changed in various ways.

A plurality of lead lines La are provided above the outer surface ES of the liquid crystal display panel PNL in the non-display area NDA and are connected to the detection electrodes Rx. Here, the lead lines La are electrically connected to the detection electrode Rx on a one-to-one basis. Each lead line La is connected to a corresponding pad arranged above the outer surface ES of the liquid crystal display panel PNL in the non-display area NDA. The flexible wiring substrate FPC2 is connected to the outer surface ES of the liquid crystal display panel PNL, and the flexible wiring substrate FPC2 is connected to the pad above the outer surface ES. Each of the lead lines La is used to take out a sensor output value from the detection electrode Rx.

The drive IC chip IC2 reads from the above detection electrode Rx a read signal indicating a change in a sensor signal generated between the electrode Tx and the detection electrode Rx during the sensing drive for performing sensing.

A detection circuit RC is, for example, built into the drive IC chip IC2. This detection circuit RC detects the contact or approach of a conductor to the input surface IS of the liquid crystal display device DSP based on the read signal (sensor output value) from the detection electrode Rx. Furthermore, the detection circuit RC can also detect position information of a point where the conductor has come in contact or has approached. Note that the detection circuit RC may also be provided in the control module CM.

Next, the operation during sensing drive for performing sensing to detect the contact or approach of a finger to the input surface IS of the liquid crystal display device DSP described above will be described. That is, write signals are written in sequence to the plurality of electrodes Tx from the common electrode driving circuit CD. In this state, sensing is performed by the sensor SE.

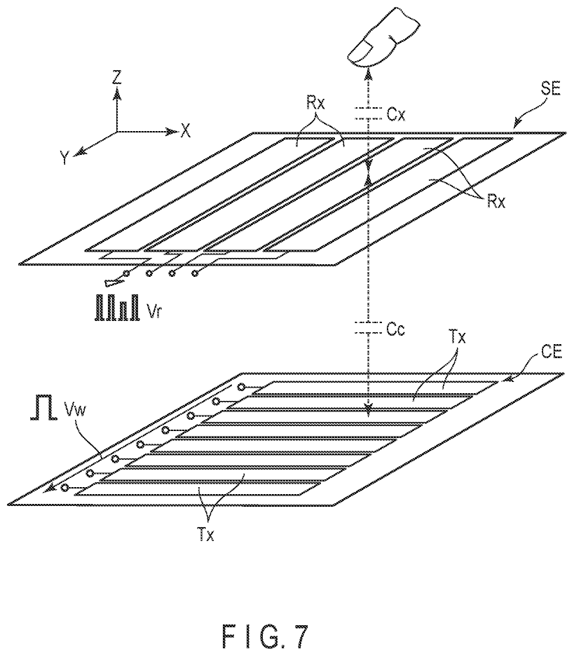

Here, the principle of one example of a sensing method is explained with reference to FIG. 7. FIG. 7 illustrates the principle of one example of the sensing method.

As shown in FIG. 7, the detection electrode Rx generates a sensor signal therebetween the electrode Tx. A capacitance Cc exists between the electrode Tx and the detection electrode Rx. That is, the detection electrode Rx is capacitively coupled with the electrode Tx.

A pulse-like write signal (sensor drive signal) Vw is sequentially written to the plurality of electrodes Tx at a predetermined cycle. In this example, the write signal Vw is sequentially written to each electrode Tx. Also, it is assumed that a user's finger is present in proximity to a position where a specific detection electrode Rx and electrode Tx intersect. The user's finger in proximity to the detection electrode Rx causes a capacitance Cx. When the pulse-like write signal Vw is written to the electrode Tx, a pulse-like read signal (sensor output value) Vr, which has a lower level than pulses obtained from other detection electrodes, is obtained from the specific detection electrode Rx. That is, when detecting input position information, which is the position information of the user's finger in the display area DA, the common electrode driving circuits CD1 and CD2 write the write signal Vw to the electrode Tx and generate a sensor signal between the electrode Tx and the detection electrode Rx. The drive IC chip IC2 is connected to the detection electrode Rx and reads the reading signal Vr indicating a change in the above sensor signal (e.g., the capacitance generated at the detection electrode Rx).

In the detection circuit RC shown in FIG. 6, two-dimensional position information of a finger in the X-Y plane of the sensor SE can be detected based on a timing when the write signal Vw is written to each electrode Tx and the read signal Vr from each detection electrode Rx. The above capacitance Cx is different between cases where the finger is close to and the finger is far from the detection electrode Rx. Therefore, the level of the read signal Vr also differs between cases where the finger is close to and far from the detection electrode Rx. Therefore, the detection circuit RC can also detect the proximity of the finger with respect to the sensor SE (a distance in the normal direction of the sensor SE) based on the level of the read signal Vr.

According to the liquid crystal display device DSP of the first embodiment configured as described above, the liquid crystal display device DSP comprises the inductor L. For the purpose of reducing the level of radiation noise (EMI) from the liquid crystal display panel PNL, the inductor L is connected to a wiring line for applying signals to the electronic circuit. The inductor L is an EMI eliminating element. This allows the radiation noise to be reduced in comparison to a case where the liquid crystal display device DSP is configured without the inductor L.

In a case where time constants of objects driven by the drive IC chip IC1 (e.g., the lead line LEa2 and the common electrode driving circuit CD1) are a concern, it is more advantageous to use the inductor L described above than electrical resistance. By using the inductor L, it is possible to take measures against the radiation noise without lowering the time constant, in other words, while suppressing an increase in the time constant.

From the above, it is possible to obtain a liquid crystal display device DSP that can reduce radiation noise.

### Second Embodiment

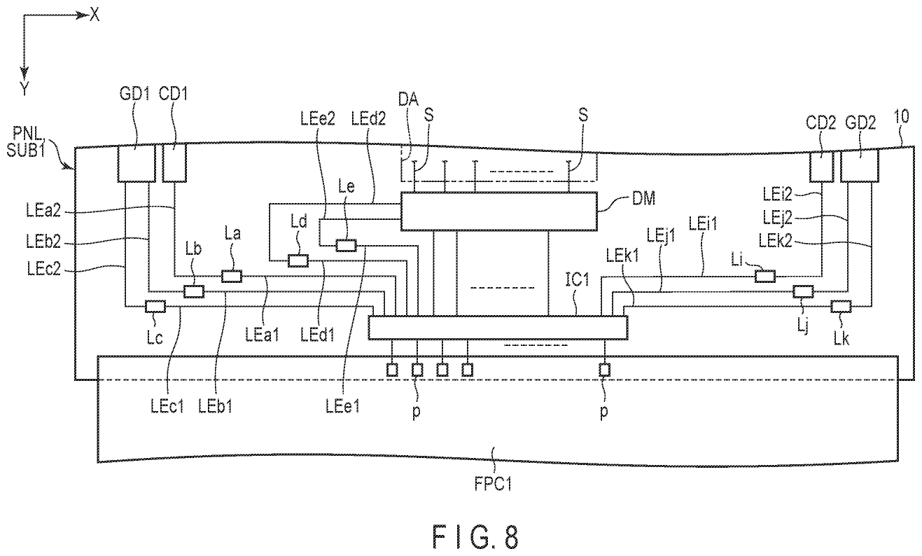

Next, a second embodiment will be described. A liquid crystal display device DSP is configured in the same manner as the first embodiment described above, except for the configuration described in the present second embodiment. FIG. 8 is a circuit diagram showing a part of the liquid crystal display device DSP with a sensor according to the second embodiment.

As shown in FIG. 8, an inductor L may be provided on a first substrate SUB1 in a case where a non-display area NDA of the first substrate SUB1 has a sufficient area for forming the inductor L. In the present embodiment, a plurality of inductors L are provided in the non-display area NDA of the first substrate SUB1.

An inductor La is electrically connected between lead lines LEa1 and LEa2.

An inductor Lb is electrically connected between lead lines LEb1 and LEb2.

An inductor Lc is electrically connected between lead lines LEc1 and LEc2.

An inductor Ld is electrically connected between lead lines LEd1 and LEd2.

An inductor Le is electrically connected between lead lines LEe1 and LEe2.

An inductor Li is electrically connected between lead lines LEi1 and LEi2.

An inductor Lj is electrically connected between lead lines LEj1 and LEj2.

An inductor Lk is electrically connected between lead lines LEk1 and LEk2.

In the present embodiment, each inductor L is a coil and is formed above a first insulating substrate 10. However, the inductor L may be an external type coil or may be mounted on a flexible wiring substrate FPC1. Alternatively, the inductor L may be a ferrite bead.

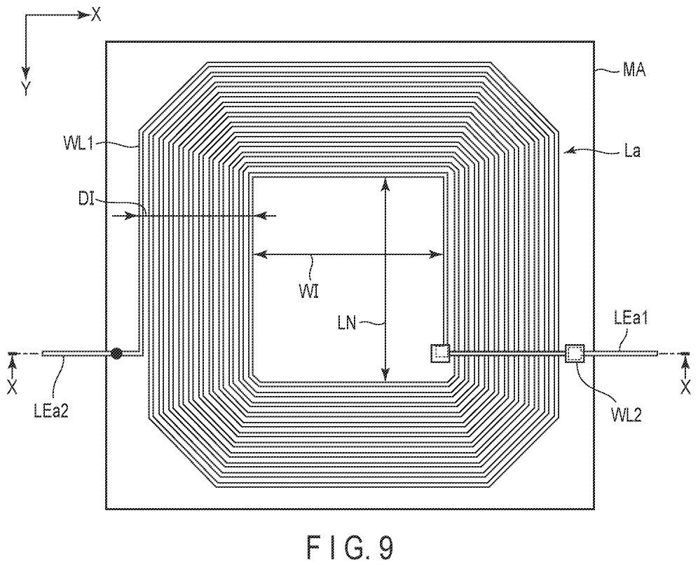

Next, the inductor La is be described representing a plurality of inductors L. FIG. 9 is a plan view showing one inductor La among the plurality of inductors L in FIG. 8 and a magnetic material MA.

As shown in FIG. 9, the inductor L has a first wiring line WL1 and a second wiring line WL2. The first wiring line WL1 is formed by winding. In the present embodiment, the winding number of the first wiring line WL1 is 12. With respect to the line and space of the first wiring line WL1, L/S=2.5/2.5 μm is established.

Therefore, with respect to a distance DI from an inner edge of a section of the first wiring line WL1 located at an innermost circumference to an outer edge of a section of the first wiring line WL1 located at an outermost circumference, DI=(2.5 μm+2.5 μm)×12=60 μm is established.

A width from an inner edge of a left side section of the first wiring line WL1 located at the innermost circumference to an inner edge of a right side section of the first wiring line WL1 located at the innermost circumference is WI. A length from an inner edge of an upper section of the first wiring line WL1 located at the innermost circumference to an inner edge of a lower section of the first wiring line WL1 located at the innermost circumference is LN. The width WI is the width in a row direction X and the length LN is the length in a columnar direction Y. WI=LN=140 μm is established.

An end portion located at the outermost circumference of the first wiring line WL1 is electrically connected to the lead line LEa2. An end portion located at the innermost circumference of the first wiring line WL1 is electrically connected to the second wiring line WL2. The second wiring line WL2 has one end portion that intersects with the first wiring line WL1 multiple times and extends to be electrically connected to the first wiring line WL1 and another end portion electrically connected to the lead line LEa1.

In the present embodiment, the inductor La is formed of the first wiring line WL1 and the second wiring line WL2 formed in a different layer from the first wiring line WL1. The first wiring line WL1, the lead line LEa1, the lead line LEa2, etc. are formed at the same time with the same material as a source line S. For example, the first wiring line WL1 and the lead line LEa2 are physically formed continuously. The second wiring line WL2 is formed at the same time with the same material as a metal layer ML.

The inductance of the inductor La is approximately 1 pH, and the resistance component of the inductor La is approximately 200Ω.

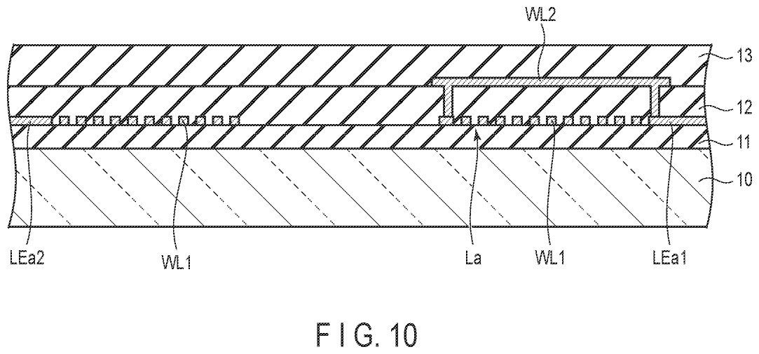

FIG. 10 is a cross-sectional view of a part of the first substrate SUB1 of the present second embodiment along line X-X in FIG. 9. In FIG. 10, the magnetic material MA is omitted.

As shown in FIG. 10, the first wiring line WL1, the lead line LEa1, the lead line LEa2, etc., of the inductor La are simultaneously formed with the same material as the source line S and covered by a second insulating layer 12. The second insulating layer 12 is an organic insulating layer formed of acrylic resin, for example. The second wiring line WL2 is formed on the second insulating layer 12 and covered by a third insulating layer 13. The second wiring line WL2 is connected to the first wiring line WL1 and the lead line LEa1 through a through hole formed in the second insulating layer 12. The third insulating layer 13 is, for example, an inorganic insulating layer made of an inorganic material.

The first wiring line WL1, the source line S, and other wirings, for example, employ a three-layer laminated structure (Ti-based/Al-based/Ti-based), respectively, comprising a lower layer configured by a metal material mainly composed of Ti, such as Ti (titanium) or an alloy containing Ti, an intermediate layer configured by a metal material mainly composed of Al (aluminum), such as Al or an alloy containing Al, and an upper layer configured by a metal material mainly composed of Ti, such as Ti or an alloy containing Ti.

The three-layer laminated structure (Ti-based/Al-based/Ti-based) is also employed, for example, for the second wiring line WL2 and wiring lines of the metal layer ML, etc.

Note that a gate line G is formed of an alloy containing Mo, such as Mo (molybdenum) and MoW (molybdenum-tungsten).

The configuration of the inductor La described above is an example and can be varied in various ways.

At least, the winding number and line and space of the first wiring line WL1, the distance DI, the width WI, and the length LN can be varied.

The first wiring line WL1 may be formed of a different metal from the source line S, and the second wiring line WL2 may be formed of a different metal from the metal layer ML. For example, the first wiring line WL1 may be formed simultaneously with the same material as the metal layer ML, and the second wiring line WL2 may be formed simultaneously with the same material as the gate line G.

The first wiring line WL1 may also be formed by connecting multiple types of metal wiring lines. For example, the first wiring line WL1 may include a portion formed simultaneously with the same material as the source line S and a portion formed simultaneously with the same material as the metal layer ML.

The magnetic material MA covers the inductor La. The magnetic material MA is formed sheet-like and covers above the inductor La. The inductor La is sandwiched between the first insulating substrate 10 and the magnetic material MA. In the present embodiment, the magnetic material MA covers an entire wound portion of the inductor La in plan view.

The magnetic material MA is located in an area of the first substrate SUB1 that is separated from the second substrate SUB2. Therefore, the inductor L should also not overlap the second substrate SUB2.

The magnetic material MA may also cover a single inductor L or two or more inductors L together. In any case, the magnetic material MA should be able to receive the magnetic field created by the inductor L. This allows the inductance of the inductor L to be increased.

In the liquid crystal display device DSP according to the second embodiment configured as described above, the same effect as in the first embodiment can be obtained, and the liquid crystal display device DSP that is able to reduce the radiation noise can be obtained.

The inductor L can be formed on the first substrate SUB1. The liquid crystal display device DSP can be formed without an external inductor. Therefore, the manufacturing cost can be suppressed. In addition, since the inductor L does not need to be provided on the flexible wiring substrate FPC1, the design of the flexible wiring substrate FPC1 can be simplified. As a result, it is possible to improve the degree of freedom in designing the entire liquid crystal display device DSP.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, a plurality of electrodes Tx may respectively extend substantially linearly in the columnar direction Y and be aligned spaced apart in the row direction X in the display area DA. In such a case, a plurality of detection electrodes Rx may be aligned spaced apart in the columnar direction Y and may extend substantially linearly in the row direction X.

The common electrode driving circuit CD may be located between the display area DA and the demultiplexer DM.

A wiring substrate connected to the first substrate SUB1, which is a semiconductor substrate, is not limited to an FPC, but may be a printed circuit board (PCB).

In the embodiments described above, a liquid crystal display device is disclosed as an example of an electronic device. However, the embodiments described above are applicable to all flat panel display devices, such as other liquid crystal display devices, organic EL (electroluminescent) display devices, other self-illuminated display devices, or electronic paper-type display devices having electrophoretic elements, etc., and are also applicable to electronic devices other than display devices.

In the embodiments described above, the first substrate (array substrate) SUB1 is disclosed as an example of a semiconductor substrate. However, the semiconductor substrate is not limited to being applied to a substrate of a display device, but can also be applied to a sensor substrate for detecting input position information, for example.

What is claimed is:

1. A semiconductor substrate comprising:
an insulating substrate;
a plurality of gate lines and a plurality of source lines formed above the insulating substrate;
a first electronic circuit formed above the insulating substrate and connected to the plurality of gate lines;
a first lead line formed above the insulating substrate and provided with a first signal;
a second lead line formed above the insulating substrate and electrically connected to the first electronic circuit; and
a first inductor provided above the insulating substrate and electrically connected between the first lead line and the second lead line.

2. The semiconductor substrate of claim 1, further comprising:
a third lead line formed above the insulating substrate and provided with a second signal;
a fourth lead line formed above the insulating substrate and electrically connected to the first electronic circuit; and
a second inductor provided above the insulating substrate and electrically connected between the third lead line and the fourth lead line.

3. The semiconductor substrate of claim 1, further comprising:
a second electronic circuit formed above the insulating substrate and connected to the plurality of source lines;
a third lead line formed above the insulating substrate and provided with a second signal;
a fourth lead line formed above the insulating substrate and electrically connected to the second electronic circuit; and
a second inductor provided above the insulating substrate and electrically connected between the third lead line and the fourth lead line.

4. The semiconductor substrate of claim 3, further comprising:
a display area in which the plurality of gate lines and the plurality of source lines are provided;
a non-display area outside the display area; and
a plurality of pixel electrodes formed above the insulating substrate and located in the display area,
wherein
the first electronic circuit is a gate line driving circuit located in the non-display area and electrically connected to the plurality of pixel electrodes to drive the plurality of pixel electrodes, and
the second electronic circuit is a demultiplexer located in the non-display area and connected to the plurality of source lines.

5. The semiconductor substrate of claim 4, further comprising:
a common electrode formed above the insulating substrate, located in the display area, and having a plurality of electrodes; and
a third electronic circuit formed above the insulating substrate and located in the non-display area,
wherein
the third electronic circuit is electrically connected to the plurality of electrodes and is a circuit for driving the plurality of electrodes.

6. The semiconductor substrate of claim 5, wherein
the first inductor is located in the non-display area.

7. The semiconductor substrate of claim 4, wherein
the first inductor is located in the non-display area.

8. The semiconductor substrate of claim 1, wherein
the first inductor is a coil.

9. The semiconductor substrate of claim 8, wherein
the coil is formed above the insulating substrate.

10. The semiconductor substrate of claim 1, wherein
the first inductor is a ferrite bead.

11. An electronic device comprising:
a semiconductor substrate including an insulating substrate, a plurality of gate lines and a plurality of source lines formed above the insulating substrate, a first electronic circuit formed above the insulating substrate and connected to the plurality of gate lines, a first lead line formed above the insulating substrate and provided with a first signal, and a second lead line formed above the insulating substrate and electrically connected to the first electronic circuit;
a wiring substrate including a third lead line electrically connected to the first lead line and a fourth lead line electrically connected to the second lead line, and coupled to the semiconductor substrate; and
a first inductor provided on the wiring substrate and electrically connected between the third lead line and the fourth lead line.

12. The electronic device of claim 11, further comprising:
a second inductor,
wherein
the semiconductor substrate further includes a fifth lead line formed above the insulating substrate and provided with a second signal, and a sixth lead line formed above the insulating substrate and electrically connected to the first electronic circuit,
the wiring substrate further includes a seventh lead line electrically connected to the fifth lead line and an eighth lead line electrically connected to the sixth lead line, and
the second inductor is provided on the wiring substrate and is electrically connected between the seventh lead line and the eighth lead line.

13. The electronic device of claim 11, further comprising:
a second inductor,
wherein
the semiconductor substrate further includes a second electronic circuit formed above the insulating substrate and connected to the plurality of source lines, a fifth lead line formed above the insulating substrate and provided with a second signal, and a sixth lead line formed above the insulating substrate and electrically connected to the second electronic circuit,
the wiring substrate further includes a seventh lead line electrically connected to the fifth lead line and an eighth lead line electrically connected to the sixth lead line, and
the second inductor is provided on the wiring substrate and is electrically connected between the seventh lead line and the eighth lead line.

14. The electronic device of claim 13, wherein
the semiconductor substrate further includes a display area in which the plurality of gate lines and the plurality of source lines are provided, a non-display area outside the display area, and a plurality of pixel electrodes formed above the insulating substrate and located in the display area,
the first electronic circuit is a gate line driving circuit located in the non-display area and electrically connected to the plurality of pixel electrodes to drive the plurality of pixel electrodes, and
the second electronic circuit is a demultiplexer located in the non-display area and connected to the plurality of source lines.

15. The electronic device of claim 14, wherein
the semiconductor substrate further includes a common electrode including a plurality of electrodes formed above the insulating substrate and located in the display area, and a third electronic circuit formed above the insulating substrate and located in the non-display area, and
the third electronic circuit is electrically connected to the plurality of electrodes and is a circuit for driving the plurality of electrodes.

16. The electronic device of claim 11, wherein
the first inductor is a coil.

17. The electronic device of claim 16, wherein
the coil is formed inside the wiring substrate.

18. The electronic device of claim 11, wherein
the first inductor is a ferrite bead.
